(19) United States
(12) Patent Application Publication
(10) Pub. No.: US 2008/0216894 A1
(43) Pub. Date: Sep. 11, 2008

(54) QUANTUM DOT PHOTOVOLTAIC DEVICE

(75) Inventor: Troy D. Hammond, Pittsburgh, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 11/970,485

(22) Filed: Jan. 7, 2008

Related U.S. Application Data
(60) Provisional application No. 60/879,041, filed on Jan. 8, 2007.
(60) Provisional application No. 60/880,004, filed on Jan. 12, 2007.

(51) Int. Cl. H01L 31/04; B05D 5/12

(52) U.S. Cl. 136/263; 136/252; 427/74; 977/774; 977/742; 977/734

(57) ABSTRACT

Nanostructures and quantum dots are used in photovoltaic cells or solar cells outside of the active layer to improve efficiency and other solar cell properties. In particular, organic photovoltaic cells can benefit. The quantum dot can absorb light which is not absorbed by the active layer and emit red-shifted light which is absorbed by the active layer. The active layer, the hole transport layer, or the hole injection layer can comprise regioregular polythiophenes. Quantum dots can form a quantum dot layer, and the quantum dot layer can be found between the light source and the active layer or on the side of the active layer opposite the light source. Quantum dots can also be used in electrode layers.

### RELATED APPLICATIONS

This application claims priority to U.S. provisional applications 60/879,041 filed Jan. 8, 2007 and 60/880,004 filed Jan. 12, 2007, which are hereby incorporated by reference in their entirety.

### BACKGROUND

A photovoltaic device or solar cell converts light to electricity. Light shines onto an active layer and the interaction of the light with the components of the active layer generates an electrical current, converting light to electricity. The active layer can comprise a component that carries positive charge (or “holes”) and a second component that carries negative charge, (or electrons) and a junction between the two components. It is the junction between these components that allows or facilitates the conversion of light to electricity. The electric current can be picked up by electrodes on each side of the device and can be used to power something useful. In the photovoltaic device, one side of the active layer is typically transparent to allow light through to the active layer. The opposite side can have reflective elements to reflect light back to the active layer. Photovoltaic devices are important alternative energy sources to reduce dependence on oil.

Despite advances in photovoltaic technology, a need exists for improved photovoltaic devices or solar cells having, among other things, improved efficiencies, flexibility, stability, processing, and economic feasibility. One important approach is organic-based photovoltaic devices (OPVs) wherein an organic material is present in the active layer. In addition, nanotechnology can be used to control structure including use of nanostructures and nanofabrication methods. For example, one nanotechnology approach is to use quantum dots in the active layer of an OPV. See for example U.S. Pat. No. 6,878,871 to Scher et al. and U.S. patent Pub. 2006/0032530. Quantum dots are of interest because, for example, they have optical properties which can be precisely tuned. See also, U.S. Pat. No. 6,852,920.

U.S. Pat. No. 6,566,595 is an example of an inorganic photovoltaic device. The processing methods are relatively difficult compared to organic systems, involving use for example of molecular beam epitaxy or metal-organic chemical vapor deposition (MOCVD) to make the device. See also U.S. Pat. No. 6,444,897 to Luque-Lopez.

Quantum dots have been used in wave guides as concentrators for photovoltaic devices (see U.S. Pat. No. 6,476,312).

Quantum dots have been used as interfacial materials for solar cell devices, interfacing the electron conductor and the hole conductor of the active layer. See U.S. Pat. No. 7,042,029.

### SUMMARY

Provided herein are devices, as well as methods of making and using devices. In various devices described herein, quantum dots are used in the photovoltaic device to provide advantages such as increased photovoltaic efficiency. This can be achieved, for example, by harvesting light of colors typically not captured by the active layer.

For example, one embodiment is a photovoltaic device comprising: at least one quantum dot layer, wherein incident radiation upon the quantum dot layer is red-shifted to form red-shifted radiation, and at least one active layer which absorbs red-shifted radiation.

Another embodiment is for example a device comprising: at least one photovoltaic active layer, at least one anode, at least one cathode, and optionally, at least one additional layer, wherein the device further comprises quantum dots which are not in the active layer.

In another example, one embodiment provides an organic photovoltaic device comprising: at least one quantum dot layer, wherein incident radiation upon the quantum dot layer is red-shifted to form red-shifted radiation, and at least one active layer which absorbs red-shifted radiation.

Another embodiment provides a device comprising: at least one organic photovoltaic active layer, at least one anode, at least one cathode, and optionally, at least one additional layer, wherein the device further comprises quantum dots which are not in the active layer.

Also provided is a method of making an organic photovoltaic device comprising: providing at least one quantum dot layer formulation comprising quantum dots wherein, upon layer formation, incident radiation upon the quantum dot layer is red-shifted to form red-shifted radiation, and providing at least one organic active layer formulation which, upon layer formation, absorbs red-shifted radiation, forming the quantum dot layer from the formulation, and forming the organic active layer from the formulation.

Also provided is an organic photovoltaic device comprising: at least one nanostructured layer, wherein incident radiation upon the quantum dot layer is red-shifted to form red-shifted radiation, and at least one organic active layer which absorbs red-shifted radiation. The nanostructured layer can be a quantum dot layer and the nanostructures can be quantum dots.

One or more advantages for at least one embodiment include, for example, improved photovoltaic current efficiency, improved barrier properties including protection of OPV active layer against harsh blue/UV light, better lifetime, ability to use technology with existing OPV technology, and low cost.

### DESCRIPTION OF THE DRAWINGS

FIG. 1 illustrates generically a first embodiment wherein the quantum dot layer is on the light source side of the active layer.

FIG. 2 illustrates a second embodiment which is more detailed compared to FIG. 1.

FIG. 3 illustrates generically a third embodiment wherein the quantum dot layer is opposite to the light source side of the active layer.

FIG. 4 illustrates a fourth embodiment which is more detailed compared to FIG. 3.

FIG. 5 illustrates a fifth embodiment in which the quantum dots are mixed with the cathode materials.

FIG. 6 illustrates a sixth embodiment wherein a quantum dot layer is both on the light source side of the active layer and the opposite side of the light source.

### DETAILED DESCRIPTION

### Introduction

All references cited herein are incorporated by reference in their entirety for all purposes.

Photovoltaic devices and organic photovoltaic devices are generally known in the art. Examples can be found in, for example:

U.S. patent Publication 2006/0076050 to Williams et al., “Heteroatomic Regioregular Poly(3-Substitutedthiophenes) for Photovoltaic Cells,” (Plextronics) which is hereby incorporated by reference including working examples and drawings.

U.S. patent Publication 2006/0237695 (Plextronics), “Copolymers of Soluble Poly(thiophenes) with Improved Electronic Performance,” which is hereby incorporated by reference including working examples and drawings.

U.S. Pat. No. 7,147,936 to Louwet et al.

In addition, U.S. Patent Publication 2006/0175582 “Hole Injection/Transport Layer Compositions and Devices” describes hole injection layer technology, (Plextronics) which is hereby incorporated by reference including working examples and drawings.

In many cases, photovoltaic devices comprise an active layer, wherein light energy is absorbed and converted to electrical energy, and an electrode system comprising anode and cathode, as well as, if needed a mechanical support system like a substrate and other optional layers like hole injection layers, hole transport layers, additional substrates, reflective layers, encapsulants, barriers, adhesives, and the like. The photovoltaic device can comprise organic active layer components, or be free of organic components in an all inorganic system, or can be a hybrid. For example, inorganic silicon systems are known.

One embodiment provides an organic photovoltaic device comprising: at least one nanostructured layer, wherein incident radiation upon the quantum dot layer is red-shifted to form red-shifted radiation, and at least one organic active layer which absorbs red-shifted radiation. Red-shifting by quantum dots is known. See for example U.S. Pat. No. 6,476,312. In a particular embodiment, the nanostructured layer is a quantum dot layer and the nanostructures are quantum dots. Nanostructures are generally known in the art, and quantum dots are also generally known in the art and can be distinguished from quantum wells and quantum wires. See for example, Owens and Poole, Introduction to Nanotechnology, Wiley-Interscience, 2003, including for example chapter 9, pages 226-256, and references cited on page 256 including Jacak et al, Quantum Dots, Springer, Berlin 1998. See also for example, Owens and Poole, Introduction to Nanotechnology, Wiley-Interscience, 2003, chapter 8, pages 194-225 for spectroscopic properties of quantum dots. Nanostructures can comprise nanoparticles. See for example Shenhar, Acc Chem. Res. 2003, 36, 549-561. Nanostructures can exhibit fluorescent properties and comprise fluorophores.

### Position of Active Layer and Quantum Dot Layer.

Devices described herein can comprise at least one active layer and at least one quantum dot layer, which are described further below. The active layer and the quantum dot layers can be different layers which are positioned in space with respect to each other. They can be in physical contact with each other although they do not need to be in physical contact with each other.

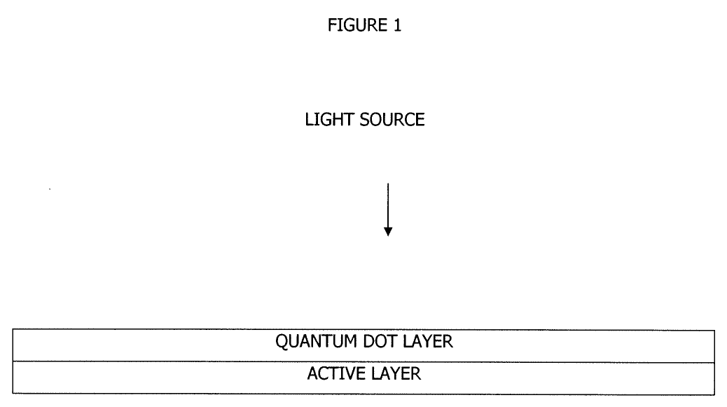

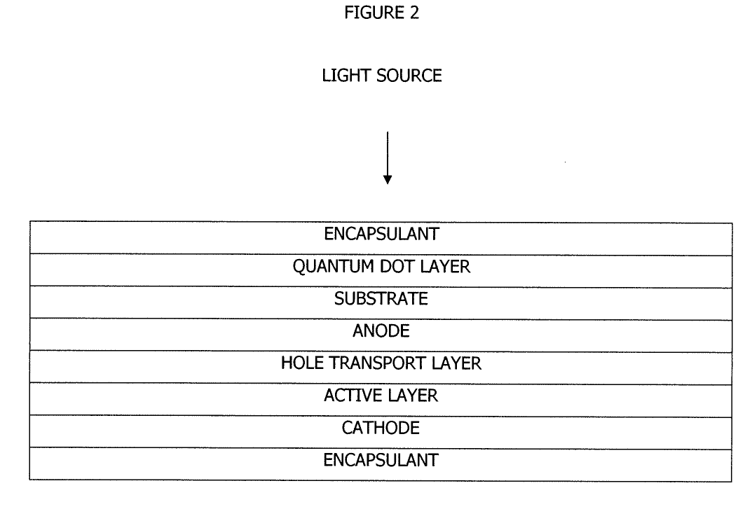

In one embodiment, the quantum dot layer is positioned with respect to the active layer so that light entering the device first interacts with the quantum dot layer before interacting with the active layer. See for example the first and second embodiments of FIGS. 1 and 2, respectively. Light emitted by the quantum dot layer can be emitted in all directions, and not all of the emitted light can be captured by the active layer. The active layer and quantum dot layer need not physically contact although that embodiment is shown in FIG. 1. One or more layers can be between the active and quantum dot layers.

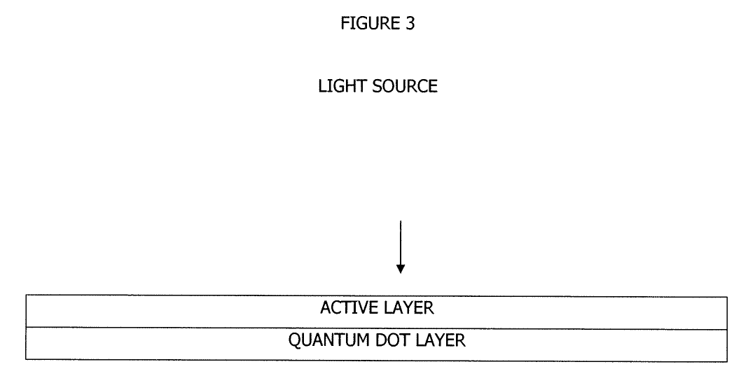

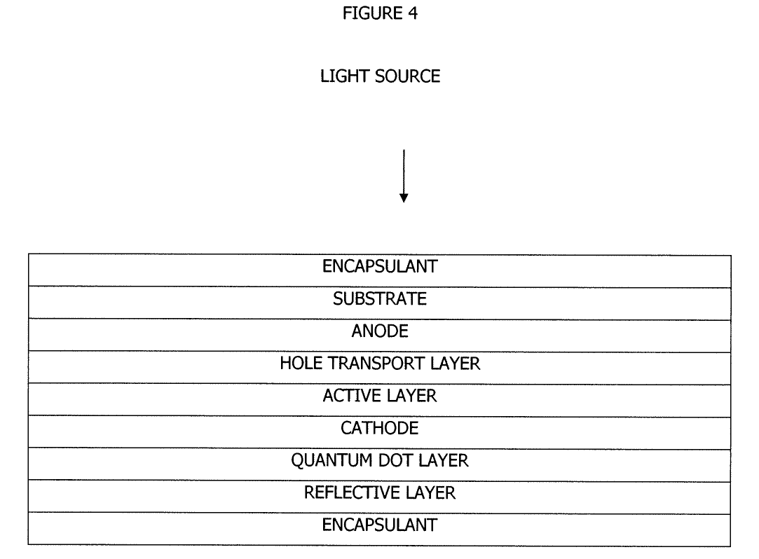

In another embodiment, the quantum dot layer is positioned with respect to the active layer so that light entering the device first interacts with the active layer before interacting with the quantum dot layer. See for example the third and fourth embodiments of FIGS. 3 and 4, respectively. In particular, with use of a reflective layer as shown in FIG. 4, a majority of light emitted from the quantum dot layer can be captured by the active layer. The active layer and quantum dot layer need not physically contact although that embodiment is shown in FIG. 3. Again, one or more layers can be in between.

The device can comprise a single quantum dot layer or multiple quantum dot layers, or the device can comprise a single active layer or multiple active layers. If multiple quantum dot or active layers are used, they can be either adjacent to each other or separated by one or more intermediate layers. Multiple layers can be adapted to function with each other to provide the desired performance.

In addition, each quantum dot layer can comprise more than one type of quantum dot, such as, for example two or more, or three or more, types of quantum dots. The different types can be for example different in the material, the size, or the size distribution.

Methods known in the art can be used to fabricate layers as shown in FIGS. 1-4 from materials described herein.

### Quantum Dot Layer

The quantum dot layer comprises one or more nanoparticulate quantum dots. The quantum dots in the layer can be the same material or can be mixtures of different materials including two or more materials. For example, the quantum dot layer can comprise a first quantum dot material, a second quantum dot material, a third quantum dot material, and the like, wherein the different dots function together to produce a desired result. The quantum dots in the layer can have substantially the same size or can be mixtures of various sizes, and the size can be for example an average particle size. For example, the quantum dot layer can comprise a first size, a second size, a third size, and the like. Quantum dots are generally known in the art and are sometimes called by other names such as “nano-dot” or “Q-dot™” or “nanocrystals” or “semiconductor nanocrystals” or “quantum crystallites,” and commercial trade names. The quantum dots can exhibit quantum confinement effects because they exist in critical dimensions where properties acutely change with changes in particle size. Nanoscale dimensions can be engineered in three dimensions. The size of a quantum dot particle can be smaller than a normal Bohr radius. See for example U.S. Pat. Nos. 5,505,928 and 5,751,018 to Alivisatos and background discussion therein, as well as U.S. Pat. No. 6,207,229 to Bawendi. See also Alivisatos, Science, 271, Feb. 16, 1996, 933-937. In particular, for embodiments described herein the quantum dot layer can comprise materials in the layer which absorb radiation of a first wavelength range and emit radiation of a second wavelength range, wherein the second wavelength is red-shifted relative to the first wavelength range. Incident radiation upon the quantum dot layer can be red-shifted to form red-shifted radiation. See for example U.S. Pat. No. 6,476,312. Quantum dots can provide fluorescence including red, orange, yellow, green, and the like fluorescence, and the fluorescence can be accurately tuned. See for example Bawendi et al., J. Physical Chemistry, B 101 (1997) 9463-75. The optical absorption and emission can be shifted to the blue with decreasing particle size. Quantum dots can exhibit broad absorption of high-energy or blue, and UV light energy, and narrower emission to the red (or lower wavelength) of the wavelength of absorption. Melting point depressions may be observed. Quantum dots are further described in patents to Quantum Dot Corp. including for example U.S. Pat. Nos. 6,274,323; 6,500,622; 6,630,307; 6,649,138; 6,653,080; 6,682,596; 6,734,420; 6,759,235; 6,815,064; and 6,838,243, as well as patents to Invitrogen including for example U.S. Pat. Nos. 7,147,917; 7,147,712; 7,144,458; 7,129,048; 7,108,915; 7,079,241; and 7,041,362, the patents describing structures, absorption and emission properties, methods of making, and methods of using. A quantum dot layer is describe in U.S. Patent Pub. 2006/0018632 to Pelka.

The quantum dots can be a variety of nanostructures. The quantum dots can be a variety of shapes and are not particularly limited by shape, but can, for example, represent spherical or substantially spherical materials, cubical, branched, tetrahedral, or elongated materials. Tetrapod materials are described by Alivisitos, U.S. Pat. No. 6,855,202. The quantum dots can be different morphologies including for example partially amorphous, crystalline, nanocrystalline, single crystalline, polycrystalline, or double crystalline.

The quantum dots can be characterized by particle size including average particle size. For example, particle size and average particle size can be for example about 1 nm to about 50 nm, or about 1 nm to about 25 nm, or about 1 nm to about 10 nm, or about 1 nm to about 5 nm. The particle size can be monodisperse so that for example at least about 50%, or at least about 75%, or at least about 85% of the particles fall within a desired size range of for example 1 nm to 10 nm. Different particles can be combined to provide mixtures. Particle sizes and particle size distributions can be used which provide the desired fluorescent properties of light absorption and light emission, functioning together with the light absorption of the active layer. Particle size can be based on a variety of quantum dot structures including for example core, core shell, or coated core shell particle sizes.

The quantum dots can be inorganic materials, metallic materials, and can be for example semiconductor materials including for example elements from Group II, Group III, Group IV, Group V, or Group VI including II-VI and III-V materials. Examples include binary, ternary, quaternary materials. Examples include CdS, CdSe, CdTe, InP, InAs, ZnS, ZnSe, HgTe, GaN, GaP, GaAs, GaSb, InSb, Si, Ge, AlAs, AlSb, PbSe, PbS, and PbTe. Examples of ternary materials include, for example, InGaAs and InGaN. An example of a quaternary material includes AlInGaP. In particular, quantum dots which absorb in the UV and blue light range, and which emit in the visible or near infrared can be used. In particular, CdS and CdSe can be used.

Examples of quantum dots are further described in for example U.S. Pat. No. 7,042,029 to Graetzel (for example, col. 2, line 34 to col. 3, line 3).

The quantum dot layer can be formulated to be a good film forming layer. The quantum dot layer can comprise at least two components including a quantum dot component and a matrix material component or a host material, which can function as a matrix or host for the quantum dot component. For example, the matrix material can provide more smooth surfaces and better film forming properties. The matrix material can be organic or inorganic. The matrix material can be an electrically insulating material having very low conductivity and can be for example a polymer or a synthetic polymer or an organic polymer. The matrix material can also comprise electrically conductive materials. It can be a mixture of polymers or a copolymer including a block copolymer. It can comprise a polymer having a carbon backbone or heteroatoms in the backbone. It can be a branched or linear polymer. It can be thermally cured or UV cured. It can be an amorphous or a semicrystalline polymer. Solubility can be low or high, although soluble polymers can be easier to mix with nanostructures and quantum dots. Sol-gel materials can be used. The matrix can be silica or titania. Examples of polymers include polymer carbonate, polystyrene, PMMA, epoxies, silicones, and polyethylene. The matrix material can be for example an electrically conductive matrix material component. The term “matrix” is known in the art for use as a surrounding medium for nanostructures. See for example U.S. Pat. No. 6,878,871. Quantum dot host materials including polymers are known and described in for example U.S. Pat. No. 5,260,957 to Bawendi et al. Evident Technologies (Troy, N.Y.) commercially provides composite quantum dot materials (Evicomposites™).

One skilled in the art can compare properties of quantum dots when not in the quantum dot layer with properties of the quantum dot layer itself. The matrix material may impact some properties.

The quantum dots can also comprise surface ligands or dispersants including organic molecules including for example polymers including for example water soluble or hydrophilic polymers. These can help couple the quantum dots to the matrix and improve dispersability, solubility, and redissolvability. For example, the quantum dots can be water soluble or water dispersible. See for example U.S. Pat. No. 6,251,303 to Bawendi. See also U.S. Pat. No. 6,872,450 (Evident Technologies).

Quantum dots can be single component materials in the core, or binary component materials, or alloys. The core may have a uniform distribution of components or a gradient of components that changes from center of the core to the edge of the core.

The quantum dots can have multiple components within a single particle or dot and can be for example a core-shell structure. The shell can improve properties such as fluorescence. Organic or inorganic materials can be used in the shell. For example, a shell layer such as for example a zinc layer comprising ZnS or ZnSe can enhance fluorescence. See for example U.S. Pat. No. 6,207,229 to Bawendi. Dots can have different shell materials, either inorganic or organic.

The thickness of the quantum dot layer is not particularly limited but can be for example about 1 nm to about 10 mm, or about 10 nm to about 1 mm, or about 100 nm to about 100 microns. The quantum dot layer can be thick (e.g., microns to mm) if it is transparent plastic with quantum dots ingrained in it. Regardless of thickness, it is desired that enough quantum dots are present to absorb as needed for a functioning device and improvement in properties, e.g., a good portion or majority of the “blue” light, and preferably no more than that, can be absorbed.

The layer comprising quantum dots can absorb radiation of a first wavelength range and may exhibit a peak or maximum absorption, in some limited cases, as well as peaks on shoulders, overlapping peaks, and cutoff wavelengths. Wavelength ranges for absorption can be determined by methods known in the art. The wavelength spectrum, range, and maxima can be measured by for example conventional UV-VIS methods. In particular, the first wavelength range can include absorption bands consistent with efficient solar energy collection and conversion to electric power. The quantum dot layer can have an absorption peak at between about 250 nm to about 800 nm. The range of desired absorption wavelengths and peaks in any given device may span the about 250 nm to about 800 nm range, or may span a smaller range, for example about 250 nm to about 650 nm, or about 250 to about 500 nm, or about 300 nm to about 550 nm, or about 400 nm to about 650 nm, or about 400 nm to about 500 nm. The range of desired absorption wavelengths may be provided by using a single type of quantum dot or by using more than one type of quantum dot.

The layer comprising quantum dots can then emit radiation within a second wavelength range, and generally exhibits a maximum emission or an emission peak. The wavelength range for emission can be measured by for example conventional methods. The emission spectrum of a quantum dot can have a full width at half maximum (FWHM) of from about 2 nm to about 300 nm, or from about 2 nm to about 200 nm, or from about 2 nm to about 100 nm, or from about 20 nm to about 100 nm. The emission maximum can fall within the second wavelength range and can be for example about 400 nm to about 900 nm, or alternatively about 400 nm to about 800 nm, or about 400 nm to about 700 nm, or about 400 nm to about 600 nm, or about 400 nm to about 500 nm, or about 500 nm to about 800 nm, or about 500 nm to about 700 nm, or about 500 nm to about 600 nm. The second wavelength range and peaks can be also extended up to for example 2100 nm and an active layer can be tailored accordingly. The range of desired emission wavelengths in any given device may span the entire second wavelength range or may be a smaller range. Any given quantum dot layer may have an emission maximum that is within the second wavelength range, but does not necessarily emit radiation across the entire second wavelength range. The range of desired emission wavelengths may be provided by using a single type of quantum dot or by using more than one type of quantum dot

The second wavelength range embodies wavelengths that are longer than the wavelengths embodied in the first wavelength range so, in other words, the emission is a red shifting from the absorption. Exemplary absorption and emission spectra can be found in references cited herein and in information from commercial suppliers.

In general, the quantum dot layer can be adapted to absorb light which is not absorbed by the active layer, which is described further below. For example, the active layer may absorb light in the red or near infra-red and the quantum dot layer can absorb at shorter, higher energy, (or more blue) wavelengths. The quantum dot layer can then reemit radiation in the red or near-IR region. For example, the active layer can absorb green/yellow light, the quantum dot layer can absorb to the blue of that, and the quantum dot layer can emit green. The maximum emission wavelength of the quantum dot can be chosen to overlap with the maximum absorption wavelength of the active layer.

Examples of quantum dot absorption and emission, including red-shifting, are provided in the references cited herein.

Quantum dots absorption and emission properties are further described in patents to Quantum Dot Corp. including for example U.S. Pat. Nos. 6,274,323; 6,500,622; 6,630,307; 6,649,138; 6,653,080; 6,682,596; 6,734,420; 6,759,235; 6,815,064; and 6,838,243, as well as patents to Invitrogen including for example U.S. Pat. Nos. 7,147,917; 7,147,712; 7,144,458; 7,129,048; 7,108,915; 7,079,241; and 7,041,362, and one skilled in the art can adapt the particular quantum dot to the active layer and device structure.

Quantum dots can be made by methods known in the art or obtained from commercial suppliers. See for example U.S. Pat. Nos. 5,505,928 and 5,751,018 to Alivisatos. See also Brus, “Quantum Crystallites and Nonlinear Optice,” Appl. Phys., A53, 465-474 (1991) and section on “Synthesis”; Peng, “Controlled Synthesis of High Quality Semiconductor Nanocrystals,” Struc Bond (2005) 118: 79-119, published online, Sep. 27, 2005; Cozzoli et al., “Synthesis, Properties and Perspectives of Hybrid Nanocrystal Structures,” Chemical Society Reviews, 2006, 35, 1195-1208. Quantum dots can be used in colloidal forms using wet chemical methods including with carrier solvents. Homogeneous nucleation in a fluid solvent can be carried out. Methods can include (i) high temperature inorganic precipitation in molten glasses or salts, or (ii) near room temperature precipitation using methods and materials from organometallic or polymer chemistry. Inverse micelle reactions can be used. Coordinating solvents can be used. Alternatively, quantum dots can be formed by making a thin film (e.g., by molecular beam epitaxy or chemical vapor deposition) and heating to convert the film to dot form, or alternatively by nanolithography.

Quantum dots can be deposited and otherwise patterned. See for example U.S. Pat. No. 6,503,831 to Speakman.

The quantum dot layer can be an electrode layer.

The quantum dots can be incorporated into a polymeric matrix component using commercially available materials. EviComposites are nanomaterials systems where the quantum dots have been loaded into common polymer matrix materials. EviComposites are available in production quantities in both polymeric solution and particle forms, which are greater than 50 microns. They are typically loaded at 0.1% by weight and can be custom loaded to other concentrations. For example:

a. EviComposite Polycarbonate Quantum Dot Polymeric Solutions & Particles

EviComposites are quantum dots that have been loaded into common insulating matrix materials provided in a ready-to-use form. As in standard polycarbonate materials the EviComposite Polycarbonates exhibit excellent toughness, heat resistance and dimensional stability. They have high insulating characteristics and are unchanged by temperature and heat conditions. The transparency of the material is excellent. Polycarbonates have good resistance to dilute acids, aliphatic hydrocarbons and alcohols. They have poor resistance to dilute alkalis, oils and greases, aromatic hydrocarbons and halogenated hydrocarbons. Polycarbonates are used in blends of polymers to create an optimally balanced set of properties.

b. EviComposite PMMA Quantum Dot Polymeric Solution and Particles

Polymethyl methacrylate (PMMA) is a thermoplastic with excellent transparency, optical properties and weather resistance. PMMA is a hard, rigid, optically clear plastic excellent for thermoforming, casting and fabrication. It exhibits good resistance to dilute acids, dilute alkalis, oil and greases and alcohols. It has poor resistant to aliphatic, aromatic, halogenated hydrocarbons.

c. EviComposite Polyethylene Quantum Dots—Particles Only

Polyethylene is a semi-rigid translucent, tough plastic with good chemical resistance, low water absorption and is easily processed. It is often used in making films. It has good resistance to dilute acids, dilute alkalis and alcohols. It is less resistant to aliphatic, aromatic and halogenated hydrocarbons.

### Active Layer

The active layer can comprise an electron accepting material and an electron donating material which together can provide for a photovoltaic effect or a light induced charge separation and current flow. The electron donating material can provide absorption of light to start the photovoltaic effect. Alternatively, the active layer can be called a photoactive layer.

A basic and novel feature is that the active material can consist essentially of an electron accepting material and an electron donating material. The active layer can be substantially free of quantum dots. For example, the active layer can have a concentration of quantum dots of about 10 wt. % or less, or about 5 wt. % or less, or about 1 wt. % or less, or about 0.1 wt. % or less. The amount can be for example about 0.0001 wt. % to about 10 wt. %, or about 0.0001 wt. % to about 1 wt. %.

The active layer can comprise a bulk heterojunction. A bulk heterojunction is described in for example McGehee et al., “Ordered Bulk Heterojunction Photovoltaic Cells,” GCEP Technical Report 2006, pages 1-11. See also Sariciftci, “Flexible Conjugated Polymer-Based Plastic Solar Cells: From Basics to Applications,” Proceedings of the IEEE, 93, 8, August 2005, 1429-1439.

The active layer can be an organic photovoltaic active layer.

For an electron donating material, the active layer can comprise an organic component including for example a polymeric component. The active layer can comprise at least one conjugated polymer or a polymer with conjugated double bonds which can have an electrical conductivity particularly with doping. Examples of conducting polymers include polyacetylene, polypyrrole, polythiophene, polyaniline, polyphenylenevinylene (PPV), polyphenylene, and derivatives thereof. The conducting polymer can have substituents on the side groups which provide for solubility. The conducting polymer can be a homopolymer or a copolymer including a block or segmented copolymer. The conducting polymer can be regioregular including for example a regioregular polythiophene. Examples of polythiophenes include those with substituents at the 3-position, or at the 4-position, or at the 3- and 4-position.

Conjugated polymers are described in for example Meijer et al., Materials Science and Engineering, 32 (2001), 1-40. See also, Kim, Pure Appl. Chem., 74, 11, 2031-2044, 2002.

Thiophenes and regioregular polythiophenes are described in for example McCullough, Adv. Mater., 1998, 10, 2, 93-116 and also in McCullough, Handbook of Conducting Polymers, 2^{nd} Ed., 1998, Chapter 9, 225-258. Block copolymers are described in for example U.S. Pat. No. 6,602,974. A method making regioregular polythiophenes is described in for example U.S. Pat. No. 6,166,172.

Patterning of conjugated or conducting polymers is described in for example McCullough, Langmuir, 2003, 19, 6492-6497.

For an electron accepting material, the active layer can comprise a fullerene or a fullerene derivative. The fullerene can be functionalized to provide better dispersability and solubility.

A particular example of an active layer can be P3HT/PCBM, wherein P3HT is poly(3-hexyl thiophene) and PCBM is the fullerene derivative [6,6]-phenyl-C₆₁-butyric acid methyl ester.

The thickness of the active layer can be for example about 50 nm to about 300 nm, or about 150 nm to about 200 nm.

The active layer can be annealed. Formulation and layer formation conditions can be adjusted to provide for good nanoscale dispersion of the components and better efficiencies.

The active layer absorption can be tailored to function with the quantum dot layer. For example, the active layer can have absorption which is red-shifted from for example poly(3-hexyl thiophene). This can provide for example the quantum dot layer absorbing in a region which the active layer absorbs less, and the quantum dot layer emitting in the region that the active layer absorbs.

The active layer can be capable of absorbing the radiation of the second wavelength range emitted by the quantum dot layer. A matching can be carried out with the quantum dot layer. For example, one skilled in the art can match the quantum dot layer absorption spectrum, and the quantum dot emission spectrum, with the active layer absorption properties, and bearing in mind the solar light application and the wavelengths of the solar light. One skilled in the art can balance this matching with other important properties for the photovoltaic cell.

Spectral properties, including emission and absorption, in the range of about 400 nm to about 700 nm can be tuned including red, orange, yellow, green, blue, indigo, and violet portions of the spectrum. Lower and higher energy bands outside the 400-700 range can be also used as appropriate for solar cell applications including near infrared and UV.

The active layer may also be an all inorganic active layer or a hybrid organic/inorganic active layer.

### Electrode Layers

Electrode layers can be anode or cathode. Electrodes for use in photovoltaic cells are known, and known materials can be used. Electrodes can be selected to regulate overall device properties. For example, the electrodes can be selected based on charge carrying capability, conductivity, transparency, opacity, processing, flexibility, barrier properties, or environmental tolerance.

The anode and cathode can be made of different materials. At least one electrode can be adapted to allow light to pass through and interact with the active layer. One electrode therefore can be transparent or translucent.

The electrode can be a transparent conductive material such as for example indium tin oxide.

The electrode can be a metal including for example aluminum or Ba/Al.

The electrode can directly contact the active layer.

### Hole Injection and Transport Layers and Other Layers

The optional HIL or HTL layers can be prepared from water-based formulations or organic solvent-based formulations. Conjugated polymers can be used as described above for the active layer. They can be polythiophene based including regioregular polythiophene based. They can be for example PLEXCORE HIL (Plextronics, Pittsburgh, Pa.) or PEDOT/PSS (Baytron, H. C. Stark). A matrix material can be used to improve film formation. Layer thickness can be for example about 10 nm to about 500 nm, or about 25 nm to about 300 nm, or about 40 nm to about 200 nm.

The device can also comprise a substrate such as, for example, glass onto which an electrode such as ITO is disposed and the larger OPV device can be built. A variety of substrate materials can be used including, for example, a glass, a metal, a ceramic, a polymer such as for example stainless steel foil or poly(ethylene terephthalate) (PET).

Hole and electron blocking layers can be used if desired.

One or more reflection or antireflection layers can be used.

The device can be encapsulated including if desired on both the anode and cathode sides or totally in all directions around the active layer. Examples of encapsulants include polymers including UV and thermal cure polymers like for example epoxy.

### Devices

The devices can be planar or non-planar. The devices can be convex, coiled, or in a reciprocating stack architecture.

In describing the device, reference can be made to two sides of the active layer, wherein one side is on the same side for which the device is adapted for light to pass into the device, and then the side which is adapted to be on the opposite side of the light source. Devices are further illustrated in U.S. Patent Pub. 2006/0060239 (see FIG. 1 for example).

Methods to make devices are known in the art. Continuous methods such as roll-to-roll processing can be used. For example, U.S. Pat. No. 6,878,871 describes roll-to-roll processing. See also U.S. patent Pub. 2006/0062902 to Sager for device fabrication.

In one embodiment, a first device is prepared according to the principles described and claimed herein, and a second device is prepared which is analogous except that the quantum dots are not used (this second device can be called a base device for comparison purposes). The efficiencies of the two devices can be compared and the increase in efficiency based on use of quantum dots can be measured. For example, the increase in efficiency can be for example 0.1% to about 10%, or 1% to 10%, at least 10%, at least 20%, at least 30%, at least 40%, at least 50%, at least 60%, at least 70%, at least 80%, at least 90%, or at least 100%, or at least about 200%, or at least about 300%, or at least about 400%, or at least about 500%. The efficiency can be increased at least twice, at least three times, or at least four times. Absolute value of efficiency can be at least 4%, at least 5%, at least 10%, or at least 20%, or at least 30%, or at least 40%.

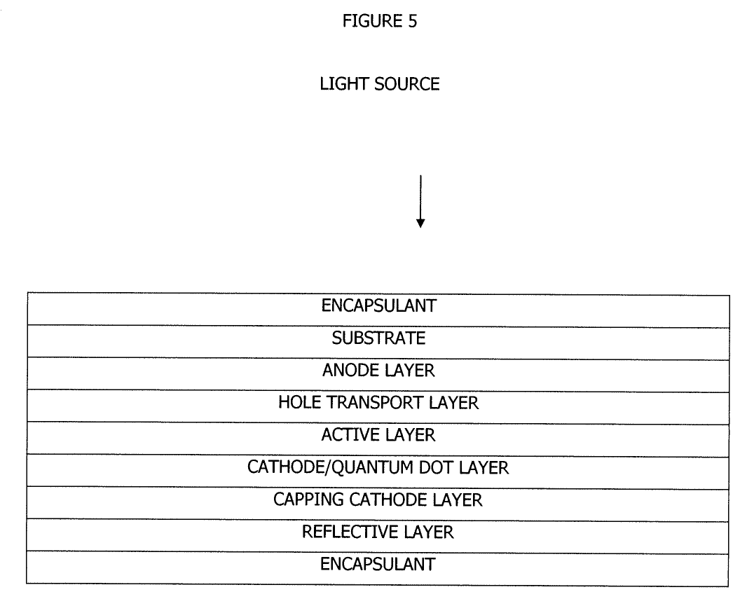

### Quantum Dot in Cathode (FIG. 5)

An alternative embodiment is illustrated in FIG. 5. Here, a cathode interlayer is used between the active layer and the capping electrode. This improves over the embodiment of FIG. 4 in that a transparent cathode is not used.

The interlayer can be a mixture of quantum dot and low resistance material such as for example metals or metal particles or metal nanoparticles or for example silver nanoparticles. For example, the weight ratio of the quantum dot content to the low resistant material content can be about 2:1 and 0.5:1. In this embodiment, a higher amount of quantum dot component may be desired.

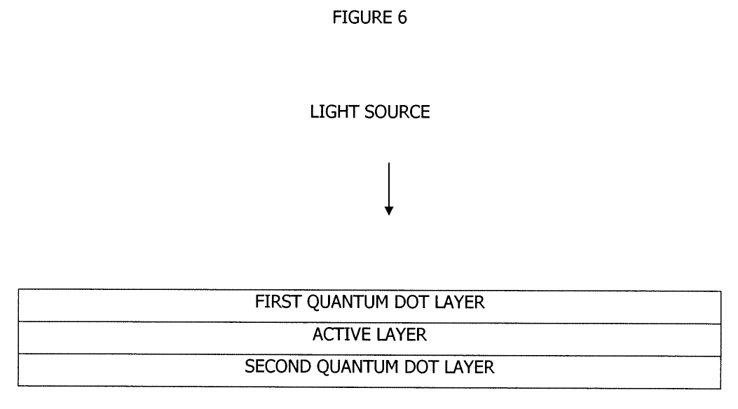

### Two Quantum Dot Layers (FIG. 6)

FIG. 6 illustrates a combination embodiment wherein at least one quantum dot layer is on the light source side of the active layer and at least one quantum dot layer is on the opposite side of the light source. Additional layers can be used as illustrated in FIGS. 2 and 4, or also FIG. 5. The active layer and multiple quantum dot layers need not physically contact although that embodiment is shown in FIG. 6.

### EXAMPLES

The photovoltaic device comprises a commercially available patterned indium tin oxide (ITO, anode) on glass substrate, a thin layer of commercially available PEDOT/PSS, a 100 nm layer of Plexcore P3HT (Plextronics, Pittsburgh, Pa.) blended with an n-type PCBM, and a Ca/Al bilayer cathode.

The patterned ITO glass substrates are cleaned with hot water and organic solvents (acetone and alcohol) in an ultrasonic bath and treated with ozone plasma. The HIL solution is then spin coated on the patterned ITO glass substrate. The film is dried at 110° C. for 10 mins in a nitrogen atmosphere. The 1.2:1 weight ratio P3HT:n-type blend in o-dichlorobenzene is then spun on the top of the HIL film with no substantial damage to the HIL (verified by AFM). The film is then annealed at 175° C. for 30 min in a glove box. Next, a 5 nm Ca layer is thermally evaporated onto the active layer through a shadow mask, followed by deposition of a 150 nm Al layer. The devices are then encapsulated and tested as follows.

A thin film of CdSe/ZnS core shell quantum dots is formulated in a 1% by weight solution of polymer (PMMA, polycarbonate or polyethylene) and spin cast onto the top of the device prepared above. The polymeric solution containing the quantum dots can be purchased from Evident Technologies, Troy, N.Y.

The photovoltaic characteristics of devices under white light exposure (Air Mass 1.5 Global Filter) are measured using a system equipped with a Keithley 2400 source meter and an Oriel 300W Solar Simulator based on a Xe lamp with output intensity of about 100 mW/cm².

What is claimed is:

1. An organic photovoltaic device comprising:
at least one quantum dot layer, wherein incident radiation upon the quantum dot layer is red-shifted to form red-shifted radiation, and
at least one active layer which absorbs red-shifted radiation.

2. The device according to claim 1, wherein the quantum dot layer is positioned with respect to the active layer so that light entering the device first interacts with the quantum dot layer before interacting with the active layer.

3. The device according to claim 1, wherein the quantum dot layer is positioned with respect to the active layer so that light entering the device first interacts with the active layer before interacting with the quantum dot layer.

4. The device according to claim 1, wherein the device comprises a single active layer or multiple active layers.

5. The device according to claim 1, wherein the device comprises a single quantum dot layer or multiple quantum dot layers.

6. The device according to claim 1, wherein the active layer consists essentially of an electron accepting material and an electron donating material.

7. The device according to claim 1, wherein the active layer is substantially free of quantum dots.

8. The device according to claim 1, wherein the active layer has a concentration of quantum dots which is about 10 wt. % or less.

9. The device according to claim 1, wherein the active layer has a concentration of quantum dots which is about 1 wt. % or less.

10. The device according to claim 1, wherein the active layer has a concentration of quantum dots which is about 0.1 wt. % or less.

11. The device according to claim 1, wherein the device further comprises a hole transport or hole injecting layer.

12. The device according to claim 11, wherein the active layer, the hole transport layer, or the hole injection layer comprises at least one conjugated polymer.

13. The device according to claim 11, wherein the active layer, the hole transport, or the hole injection layer comprises at least one polythiophene.

14. The device according to claim 11, wherein the active layer, the hole transport, or the hole injection layer comprises at least one regioregular polythiophene.

15. The device according to claim 11, wherein the active layer, the hole transport layer, or the hole injection layer comprises at least one regioregular polythiophene homopolymer or copolymer.

16. The device according to claim 1, wherein the active layer comprises at least one nanostructure.

17. The device according to claim 1, wherein the active layer comprise at least one carbon nanotube or fullerene material.

18. The device according to claim 1, wherein the active layer comprises at least one fullerene or fullerene derivative.

19. The device according to claim 1, wherein the quantum dot layer comprises at least two components including a quantum dot component and a matrix material component.

20. The device according to claim 1, wherein the quantum dot layer comprises at least two components including a quantum dot component and a polymeric matrix material component.

21. The device according to claim 1, wherein the quantum dot layer comprises at least two components including a quantum dot component and an electrically conductive matrix material component.

22. The device according to claim 21, wherein the quantum dot layer is an electrode layer.

23. The device according to claim 19, wherein the matrix material component is electrically insulating.

24. The device according to claim 1, further comprising an anode and a cathode.

25. The device according to claim 1, wherein the quantum dot layer has an absorption peak at between about 250 nm to about 800 nm.

26. The device according to claim 1, wherein the layer has an emission peak at between about 400 nm to about 900 nm.

27. The device according to claim 1, wherein the device further comprises a hole injection layer or a hole transport layer comprising regioregular polythiophene.

28. The device according to claim 1, wherein the device further comprises a hole injection layer or a hole transport layer comprising regioregular polythiophene and a different polymer.

29. The device according to claim 1, wherein the device further comprises a hole injection layer or a hole transport layer comprising a crosslinked polymer.

30. The device according to claim 1, wherein the device further comprises a transparent anode, a metallic cathode, a hole injection layer comprising polythiophene, a substrate, and encapsulants.

31. A device comprising:
at least one organic photovoltaic active layer,
at least one anode,
at least one cathode, and
optionally, at least one additional layer,
wherein the device further comprises quantum dots which are not in the active layer.

32. The device according to claim 31, wherein the quantum dots are disposed in a layer which is positioned on the side of the active layer for light transmission to the active layer.

33. The device according to claim 31, wherein the quantum dots are disposed in a layer which is positioned on the side of the active layer opposite for light transmission to the active layer.

34. The device according to claim 31, wherein the quantum dots are present in a layer contacting a device substrate.

35. The device according to claim 31, wherein the quantum dots are present in a layer which is an electrode layer.

36. The device according to claim 31, wherein incident radiation upon the quantum dots is red-shifted to form red-shifted radiation, and the active layer absorbs red-shifted radiation.

37. The device according to claim 31, further comprising a hole injection layer or hole transport layer comprising regioregular polythiophene.

38. The device according to claim 31, wherein the photovoltaic active layer comprises a conjugated polymer and a fullerene or fullerene derivative.

39. The device according to claim 31, wherein the quantum dots are present in a mixture comprising quantum dots and at least one matrix material.

40. The device according to claim 31, wherein the quantum dots improve photovoltaic efficiency of the device.

41. A method of making an organic photovoltaic device comprising:
providing at least one quantum dot layer formulation comprising quantum dots wherein, upon layer formation, incident radiation upon the quantum dot layer is red-shifted to form red-shifted radiation, and
providing at least one organic active layer formulation which, upon layer formation, absorbs red-shifted radiation,
forming the quantum dot layer from the formulation, and
forming the organic active layer from the formulation.

42. An organic photovoltaic device comprising:
at least one nanostructured layer, wherein incident radiation upon the quantum dot layer is red-shifted to form red-shifted radiation, and
at least one organic active layer which absorbs red-shifted radiation.

43. The organic photovoltaic device according to claim 42, wherein the nanostructured layer is a quantum dot layer comprising quantum dot nanostructures.

44. A photovoltaic device comprising:
at least one quantum dot layer, wherein incident radiation upon the quantum dot layer is red-shifted to form red-shifted radiation, and
at least one active layer which absorbs red-shifted radiation.

45. A device comprising:
at least one photovoltaic active layer,
at least one anode,
at least one cathode, and
optionally, at least one additional layer,
wherein the device further comprises quantum dots which are not in the active layer.
